(19) United States
(12) Patent Application Publication
(10) Pub. No.: US 2025/0344415 A1
(43) Pub. Date: Nov. 6, 2025

(54) MEMORY ARCHITECTURES WITH PARTIALLY FILLED PIERS

(71) Applicant: Micron Technology, Inc., Boise, ID (US)

(72) Inventors: Rajasekhar Venigalla, Boise, ID (US); Paolo Fantini, Vimercate (MB) (IT); Farrell M. Good, Meridian, ID (US); Lorenzo Fratin, Buccinasco (MI) (IT); Enrico Varesi, Milano (MI) (IT); Fabio Pellizzer, Boise, ID (US)

(21) Appl. No.: 18/789,168

(22) Filed: Jul. 30, 2024

Related U.S. Application Data
(60) Provisional application No. 63/643,278, filed on May 6, 2024.

(51) Int. Cl. H10B 99/00

(52) U.S. Cl. CPC H10B 99/10

(57) ABSTRACT

Methods, systems, and devices for memory architectures with partially filled piers are described. A stack of materials including alternating layers of nitride and oxide may be formed, and piers and pillars may be formed through the stack of materials. Layers of nitride may be etched for metallization and one or more piers may be removed, which may result in corresponding cavities being formed in the stack of materials. Memory cells may be formed between one or more pillars and corresponding electrodes, and the cavities (e.g., the cavities resulting from removing one or more piers) may be partially filled with a dielectric material such that an air gap is formed within the cavity, or with a low-k dielectric material, or both.

### CROSS REFERENCE

The present application for patent claims priority to U.S. Patent Application No. 63/643,278 by Venigalla et al., entitled “MEMORY ARCHITECTURES WITH PARTIALLY FILLED PIERS,” filed May 6, 2024, which is assigned to the assignee hereof, and which is expressly incorporated by reference in its entirety herein.

### TECHNICAL FIELD

The following relates to one or more systems for memory, including memory architectures with partially filled piers.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory array that supports memory architectures with partially filled piers in accordance with examples as disclosed herein.

FIG. 2 shows a top view of an example of a memory array that supports memory architectures with partially filled piers in accordance with examples as disclosed herein.

FIGS. 3A and 3B show side views of an example of a memory array that supports memory architectures with partially filled piers in accordance with examples as disclosed herein.

FIGS. 4A and 4B show aspects of a memory architecture that supports partially filled piers in accordance with examples as disclosed herein.

FIGS. 5A-5F show example aspects of a manufacturing process that supports memory architectures with partially filled piers in accordance with examples as disclosed herein.

FIGS. 6A-6F show example aspects of a manufacturing process that supports memory architectures with partially filled piers in accordance with examples as disclosed herein.

FIG. 7A-7H show example aspects of a manufacturing process that supports memory architectures with partially filled piers in accordance with examples as disclosed herein.

FIGS. 8 and 9 show flowcharts illustrating a method or methods that support memory architectures with partially filled piers in accordance with examples as disclosed herein.

### DETAILED DESCRIPTION

In some semiconductor manufacturing processes, memory cells may be formed within a memory architecture based on performing a series of processing steps. For example, after a stack of materials including alternating layers of nitride and oxide are formed, piers may be formed through the stack of materials to provide mechanical support for subsequent processing steps. In some alternative processes, trenches may be formed in the stack of materials and then the piers may be formed. Next, cavities for pillars may be formed through the stack of materials (or cavities may be formed through the material included in the trenches), and the layers of nitride may be replaced (e.g., metalized) with a metal to form access lines (e.g., word lines). Then, electrodes may be formed in the cavities and etched back to provide space for the pillars and the memory cells. The pillars may be formed within the cavities and the memory cells may be formed between the pillars and the electrodes.

Such memory architectures may have a relatively high density. That is, such memory architectures may include a relatively large quantity of memory cells located within a relatively small area, which may subject various elements to capacitive coupling (e.g., cross-coupling). Specifically, the pillars may be capacitively coupled to each other through respective piers, which may adversely affect the operation of one or more memory cells or other components of the memory architecture. Accordingly, a memory architecture having a reduced likelihood of capacitive coupling between pillars (e.g., through respective piers) may be desirable.

In accordance with examples as described herein, a memory architecture having a reduced likelihood of capacitive coupling between pillars may be formed with a series of processing steps. For example, after a stack of materials including alternating layers of nitride and oxide are formed, piers and pillars may be formed through the stack of materials (e.g., either through a pier-and-pillar process or a trench-and-pier process). Then, the layers of nitride may be etched for metallization and one or more piers may be removed, which may result in corresponding cavities being formed in the stack of materials. Memory cells may be formed between one or more pillars and corresponding electrodes, and the cavities (e.g., the cavities resulting from removing one or more piers) may be partially filled. In some instances, partially filling a pier may include depositing a dielectric material such that an air gap is formed within the cavity, filling the pier with a low-k dielectric material (e.g., a material with a small dielectric constant relative to silicon dioxide (SiO₂)), or both. The presence of the air gap, low-k dielectric, or both may reduce capacitive coupling effects between pillars that may otherwise occur. Accordingly, the memory architecture described herein may reduce a likelihood of capacitive coupling between pillars, which may improve its overall performance.

In addition to applicability in memory systems as described herein, techniques for memory architectures with partially filled pillars may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing cross-coupling effects that would otherwise occur by filling (e.g., completely filling, fully filling) the piers, among other benefits.

Features of the disclosure are illustrated and described in the context of memory devices and arrays. Features of the disclosure are further illustrated and described in the context of memory architectures, manufacturing processes, and flowcharts.

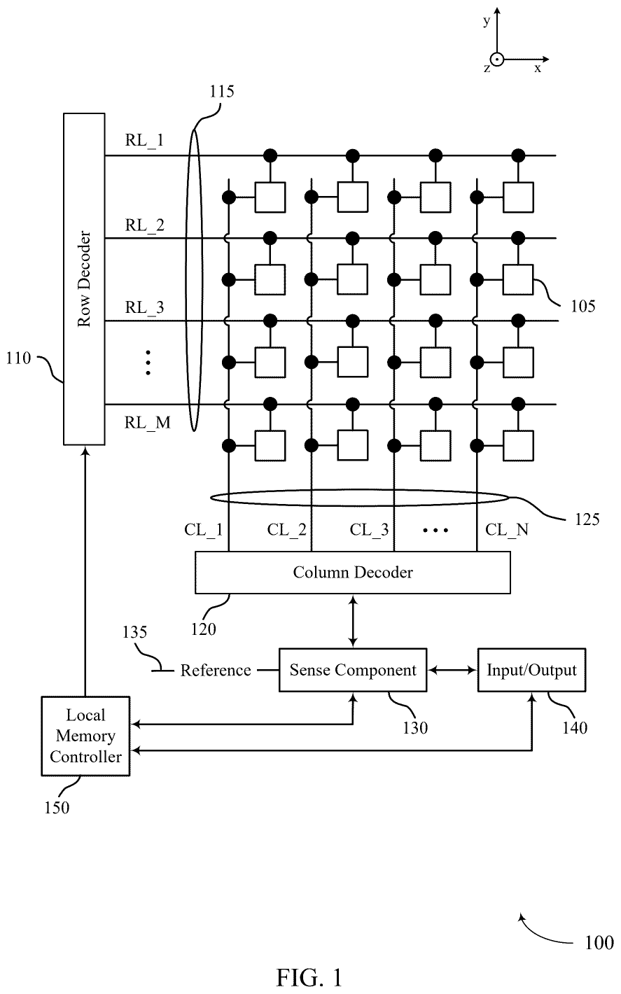

FIG. 1 shows an example of a memory device 100 that supports memory architectures with partially filled piers in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state, where a corresponding “threshold voltage” may refer to a voltage at which or above which the memory cell 105 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics (e.g., resistivity characteristics, conductivity characteristics) of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

In accordance with examples as described herein, a memory architecture having a reduced likelihood of capacitive coupling between pillars may be formed with a series of processing steps. For example, after a stack of materials including alternating layers of nitride and oxide are formed, piers and pillars may be formed through the stack of materials (e.g., either through a pier-and-pillar process or a trench-and-pier process). Then, the layers of nitride may be etched for metallization and one or more piers may be removed, which may result in corresponding cavities being formed in the stack of materials. Memory cells 105 may be formed between one or more pillars and corresponding electrodes, and the cavities (e.g., the cavities resulting from removing one or more piers) may be partially filled. In some instances, partially filling a pier may include depositing a dielectric material such that an air gap is formed within the cavity, filling the pier with a low-k dielectric material (e.g., a material with a small dielectric constant relative to silicon dioxide (SiO₂)), or both. The presence of the air gap, low-k dielectric, or both may reduce capacitive coupling effects between pillars that may otherwise occur. Accordingly, the memory architecture described herein may reduce a likelihood of capacitive coupling between pillars, which may improve its overall performance.

The memory device 100 may include any quantity of non-transitory computer readable media that support memory architectures with partially filled piers. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

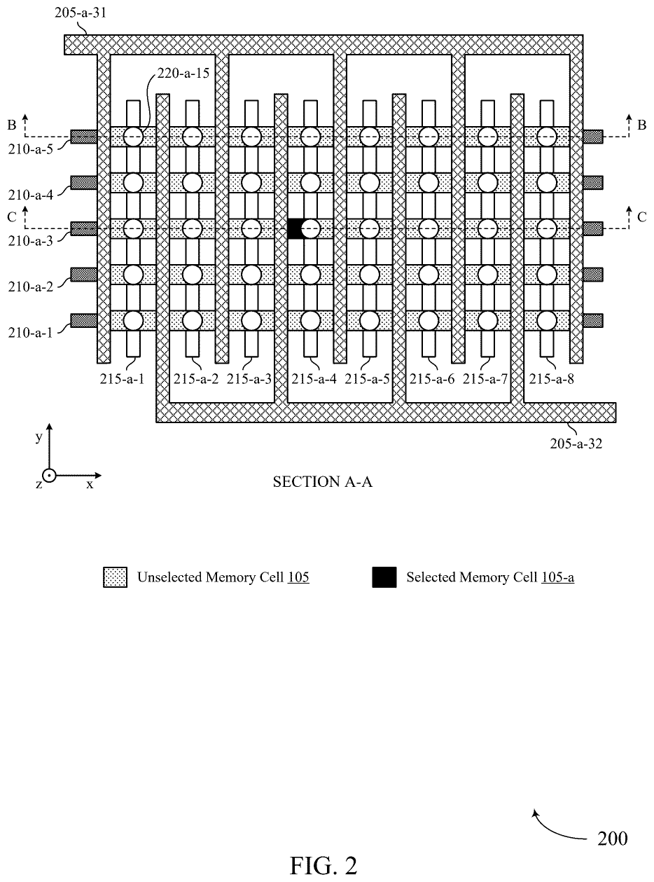

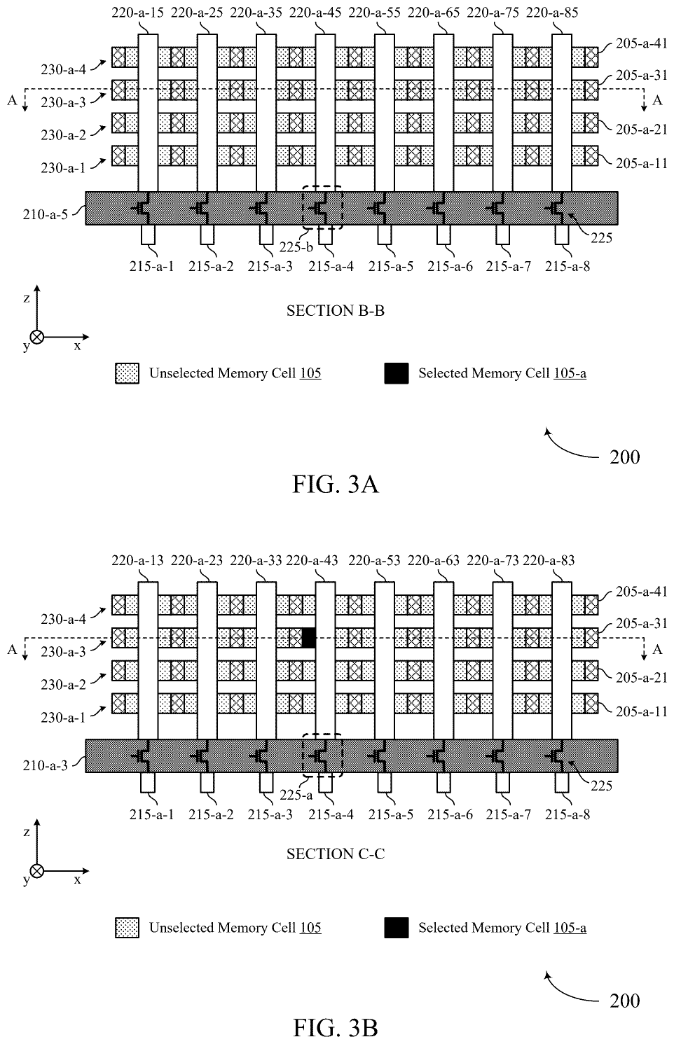

FIGS. 2, 3A, and 3B show an example of a memory array 200 that supports memory architectures with partially filled piers in accordance with examples as disclosed herein. The memory array 200 may be included in a memory device 100, and illustrates an example of a three-dimensional arrangement of memory cells 105 that may be accessed by various conductive structures (e.g., access lines). FIG. 2 illustrates a top section view (e.g., SECTION A-A) of the memory array 200 relative to a cut plane A-A as shown in FIGS. 3A and 3B. FIG. 3A illustrates a side section view (e.g., SECTION B-B) of the memory array 200 relative to a cut plane B-B as shown in FIG. 2. FIG. 3B illustrates a side section view (e.g., SECTION C-C) of the memory array 200 relative to a cut plane C-C as shown in FIG. 2. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2, 3A, and 3B. Although some elements included in FIGS. 2, 3A, and 3B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 3A and 3B). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 3A, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=Vread, which may be a positive voltage or a negative voltage) across the memory cell 105. In some examples, a logic state of the memory cell 105 may be evaluated based on whether the memory cell 105 thresholds (e.g., transitions to a relatively lower-resistance or conductive state, permits current) in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In accordance with examples as described herein, a memory architecture having a reduced likelihood of capacitive coupling between pillars 220 may be formed with a series of processing steps. For example, after a stack of materials including alternating layers of nitride and oxide are formed, piers and pillars 220 may be formed through the stack of materials (e.g., either through a pier-and-pillar process or a trench-and-pier process). Then, the layers of nitride may be etched for metallization and one or more piers may be removed, which may result in corresponding cavities being formed in the stack of materials. Memory cells 105 may be formed between one or more pillars 220 and corresponding electrodes, and the cavities (e.g., the cavities resulting from removing one or more piers) may be partially filled. In some instances, partially filling a pier may include depositing a dielectric material such that an air gap is formed within the cavity, filling the pier with a low-k dielectric material (e.g., a material with a small dielectric constant relative to silicon dioxide (SiO₂)), or both. The presence of the air gap, low-k dielectric, or both may reduce capacitive coupling effects between pillars 220 that may otherwise occur. Accordingly, the memory architecture described herein may reduce a likelihood of capacitive coupling between pillars 220, which may improve its overall performance.

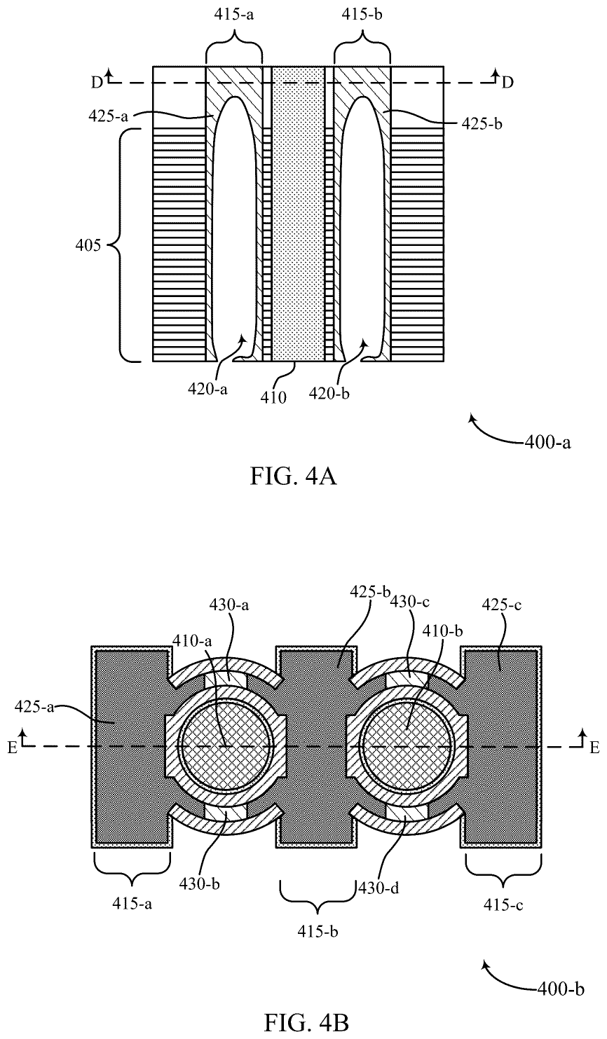

FIG. 4A shows an example of a side view of a memory architecture 400-a that supports partially filled piers in accordance with examples as disclosed herein. The memory architecture 400-a may illustrate a stack of materials 405, a pillar 410, and one or more cavities 415 along Section D-D. The cavities 415 may include respective portions 420 that include an air gap or a low-k dielectric material. The presence of the air gap, low-k dielectric, or both may reduce capacitive coupling effects between pillars 410 that may otherwise occur. Accordingly, the memory architecture 400-a may reduce a likelihood of capacitive coupling between pillars 410, which may improve its overall performance.

To form the portions 420, respective piers may have been formed in the stack of materials 405 during a prior processing step. The respective piers may have been removed (e.g., exhumed) to form the cavities 415. Additionally, or alternatively, the cavities 415 may have been filled (e.g., partially filled) with a dielectric material 425 (e.g., a fourth material). In some instances, partially filling the cavities 415 with the dielectric material 425 may result in air gaps being formed within the respective cavities 415. That is, in some instances, the portions 420 may represent air gaps within the cavities 415 that may reduce capacitive coupling effects between pillars 410 (e.g., between adjacent pillars 410).

In other examples, the dielectric material 425 may be a low-k dielectric material such as a fluorine-doped silicon dioxide, an organosilicate glass (OSG), a porous silicon dioxide, a porous OSG, a spin-on organic polymetric dielectric, or a spin-on silicon based polymeric dielectric. In such instances, the dielectric material 425 may fill (e.g., occupy) at least some or all of the respective portions 420 (not shown). In other instances, the low-k dielectric material may be air (e.g., air with a relative permittivity value of ˜1.0) such that the portions 420 represent air gaps within the cavities 415. In either instance, the presence of the low-k dielectric material may reduce capacitive coupling effects between pillars 410 (e.g., between adjacent pillars 410).

FIG. 4B shows an example of a top-down view of a memory architecture 400-b that supports partially filled piers in accordance with examples as disclosed herein. The memory architecture 400-b may illustrate one or more pillars 410, one or more cavities 415 filled with a material 425, and one or more memory cells 430 along section E-E. As described with reference to FIG. 4A, the cavities 415 may include respective portions that include an air gap or a low-k dielectric material. The presence of the air gap, low-k dielectric, or both may reduce capacitive coupling effects between pillars 410 that may otherwise occur. In some instances, FIG. 4B may show one or more additional pillars 410, cavities 415, or memory cells 430 than FIG. 4A. That is, FIG. 4A may illustrate a singular pillar, whereas FIG. 4B may include multiple pillars 410 (e.g., pillar 410-a and pillar 410-b). A person having ordinary skill in the art would understand the differences between FIGS. 4A and 4B, including the additional components and structures illustrated by FIG. 4B. Accordingly, the memory architecture 400-b may reduce a likelihood of capacitive coupling between pillars 410, which may improve its overall performance.

In some examples, the memory architecture 400-b may have included one or more piers during a prior manufacturing step. The respective piers may have been removed (e.g., exhumed) to form the cavities 415. Additionally, or alternatively, the cavities 415 may have been filled (e.g., partially filled) with a dielectric material 425 (e.g., a fourth material). In some instances, partially filling the cavities 415 with the dielectric material 425 may result in air gaps being formed within the respective cavities 415. That is, in some instances, the portions within the cavities 415 may represent air gaps within the cavities 415 that may reduce capacitive coupling effects between pillars 410 (e.g., between adjacent pillars 410).

Additionally, or alternatively, the manufacturing steps described herein may result in the formation of one or more memory cells 430 coupled with the pillars 410. For example, the pillar 410-a may be coupled with a first memory cell 430-a and second memory cell 430-b. Further, the pillar 410-b may be coupled with a third memory cell 430-c and a fourth memory cell 430-d. In some instances, the memory cells 430 may be symmetrically placed about a pier (e.g., about a cavity 415, about the line D-D). For example, the memory cells 430-a and the memory cell 430-b may be symmetrical with the memory cell 430-c and the memory cell 430-d about the cavity 425-b. In some instances, one or more of the cavities 415 (such as the cavity 425-b) may not have been exhumed and may instead be a pier. That is, as shown in FIG. 4B, a pier may exist where cavity 425-b is depicted. Accordingly, the processes described herein may reduce capacitive coupling effects between pillars 410, which may improve the associated system's overall performance.

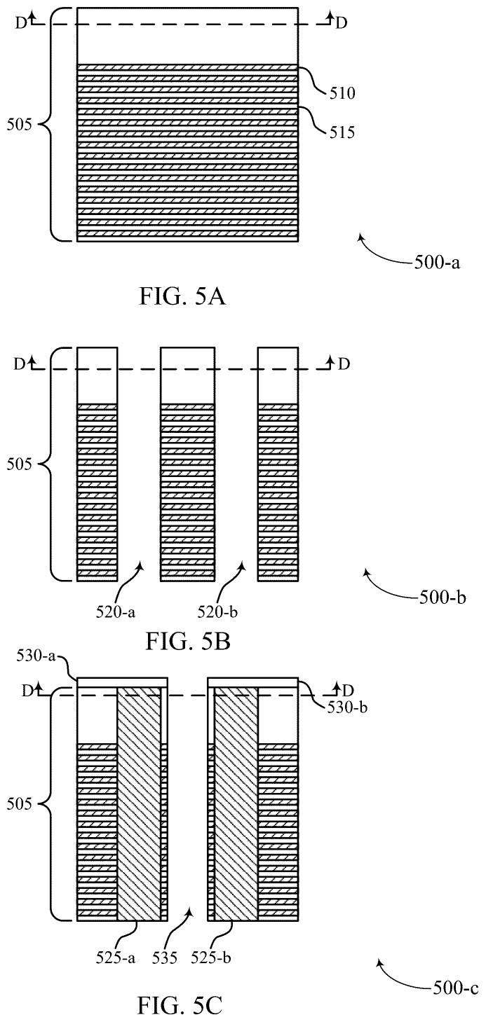

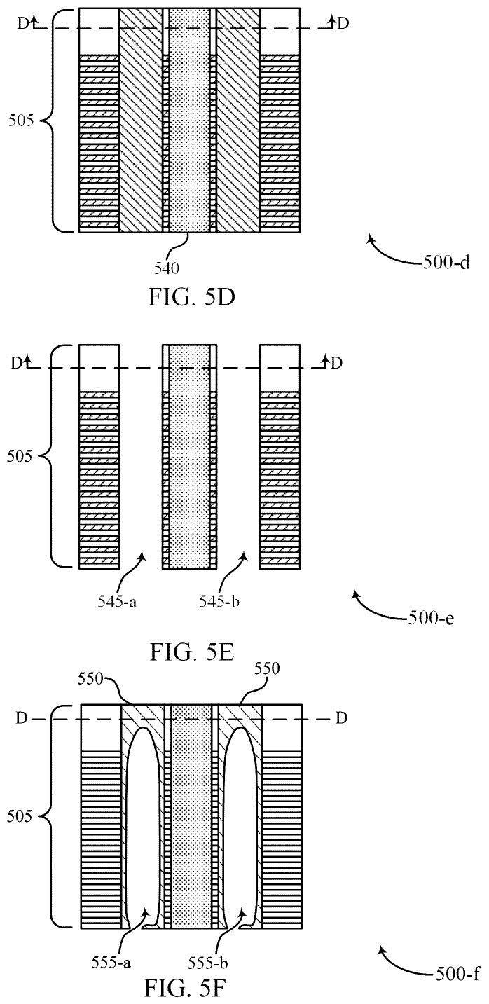

FIG. 5A shows an example of a processing step 500-a that supports memory architectures with partially filled piers in accordance with examples as disclosed herein. The processing step 500-a may include depositing a stack of materials 505. In some instances, the stack of materials 505 may include one or more layers of a nitride material 510 (e.g., a first material) and one or more materials of an oxide material 515 (e.g., a second material). The nitride material 510 and the oxide material 515 may alternate layers in the stack of materials 505. As used herein, a nitride (e.g., a nitride material) may refer to a compound of Nitrogen (N), such as an inorganic compound of N. A nitride may be a wide-bandgap semiconductor. Additionally, or alternatively, an oxide (e.g., an oxide material) may refer to a compound that is composed of an anion and a cation. An oxide may have relatively high thermal and electrical insulation properties.

FIG. 5B shows an example of a processing step 500-b that supports memory architectures with partially filled piers in accordance with examples as disclosed herein. The processing step 500-b may include etching (e.g., removing) one or more portions 520 of the stack of materials 505. For example, a first portion 520-a of the stack of materials 505 may be etched (e.g., removed) and a second portion 520-b of the stack of materials 505 may be etched (e.g., removed). Each of the portions 520 may be etched using either a wet etching operation or a dry etching operation. In some instances, respective piers may be formed in the portions 520 in subsequent processing steps.

FIG. 5C shows an example of a processing step 500-c that supports memory architectures with partially filled piers in accordance with examples as disclosed herein. The processing step 500-c may include depositing a material in the portions 520 to form respective piers 525. In some examples, the material may include a dielectric material or another type of material. As used herein, a pier 525 may refer to the filled portion in the stack of materials 505 that is configured to provide mechanical support for other components or structures of the memory architecture. In some cases, a pier 525 may be implemented to facilitate performing processing steps for forming the memory architecture. Additionally, or alternatively, each pier 525 may include a respective cap 530 (e.g., a dielectric cap). In some instances, the respective caps 530 may be located above (e.g., on top of) the stack of materials 505.

Additionally, or alternatively, the processing step 500-c may include performing a metallization process (e.g., a replacement gate (RG) process) to form the memory cells. For example, the layers of the nitride material 510 in the stack of materials 505 may be replaced (e.g., metalized) with a metal (e.g., a sixth material) to form access lines (e.g., word lines). The processing step 500-c may also include etching (e.g., removing) one or more portions 535 of the stack of materials 505. For example, a portion 535 of the stack of materials 505 may be etched (e.g., removed) using either a wet etching operation or a dry etching operation. In some instances, electrodes may be formed in the portion 535 and etched back to provide space for the pillars and the memory cells. In some instances, a pillar may be formed in the portion 535 in subsequent processing steps.

FIG. 5D shows an example of a processing step 500-d that supports memory architectures with partially filled piers in accordance with examples as disclosed herein. The processing step 500-d may include depositing a material (e.g., a third material) in the portion 535 to form a pillar 540. In some examples, the material may include a conductive material or another type of material. As used herein, a pillar 540 may refer to the filled portion in the stack of materials 505 that is supplied with voltages to activate the respective memory cells associated with the respective pillar 540. In some cases, a pillars 540 may be formed between each pier 525 and memory cells may be formed between the pillar 540 and the electrodes.

FIG. 5E shows an example of a processing step 500-e that supports memory architectures with partially filled piers in accordance with examples as disclosed herein. The processing step 500-e may include etching (e.g., removing) one or more piers 525 to form respective cavities 545. For example, a first pier 525-a may be etched (e.g., removed) to form a first cavity 545-a, and a second pier 525-b may be etched (e.g., removed) to form a second cavity 545-b. As described herein, in some examples, each pier 525 in the stack of materials 505 may be etched, whereas in other examples only a subset of the piers 525 (e.g., every other pier 525) may be etched. The etched piers 525 may be etched using either a wet etching operation or a dry etching operation. In some cases, memory cells may be formed between the pillar 540 and the electrodes after removing the piers 525.

FIG. 5F shows an example of a processing step 500-f that supports memory architectures with partially filled piers in accordance with examples as disclosed herein. The processing step 500-f may include depositing a material 550 (e.g., a fourth material) in the cavities 545. In some instances, the filled cavities 545 may include a respective portion 555 after depositing the material 550. The respective portions 555 may be completely surrounded by the material 550, or may be partially surrounded by the material 550. For example, before depositing the material 550, another material (e.g., a fifth material) may have been deposited in the cavity 545 (not shown). In some examples, the fifth material may be deposited on the sidewalls of the cavity 545 to narrow a dimension of the opening of the cavity 545.

In some examples, the material 550 may include a dielectric material, a low-k material, or both. In some examples, partially filling the cavities 545 with the material 550 may result in air gaps being formed within the respective cavities 545. That is, in some instances, the portions 555 may represent air gaps within the cavities 545 or a low-k material in the cavities, each of which may reduce capacitive coupling effects between pillars 540 (e.g., between adjacent pillars 540).

In other examples, the material 550 may be a low-k dielectric material. In such instances, the material 550 may fill (e.g., occupy) at least some or all of the respective portions 555 (not shown). In other instances, the low-k dielectric material may be air, such that the portions 555 represent air gaps within the cavities 545. In either instance, the presence of the low-k dielectric material may reduce capacitive coupling effects between pillars 540, which may improve the associated system's overall performance.

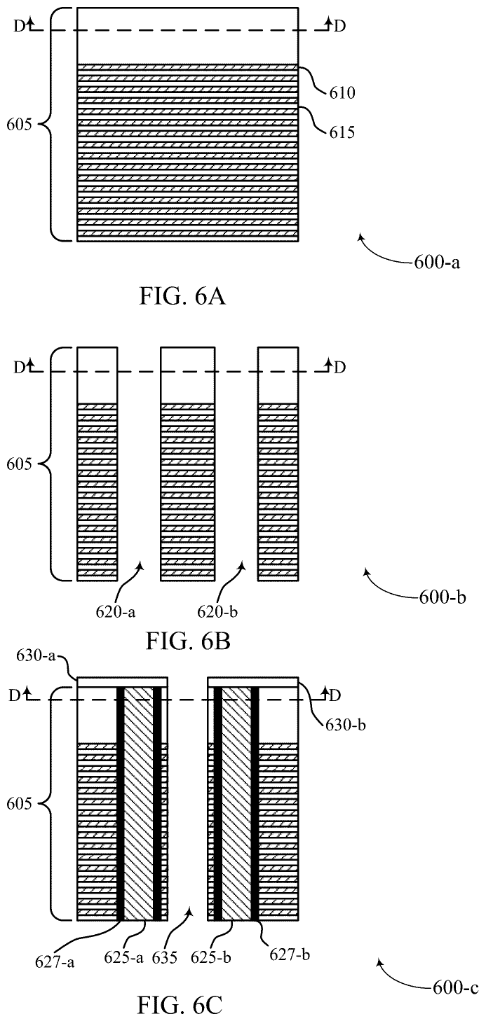

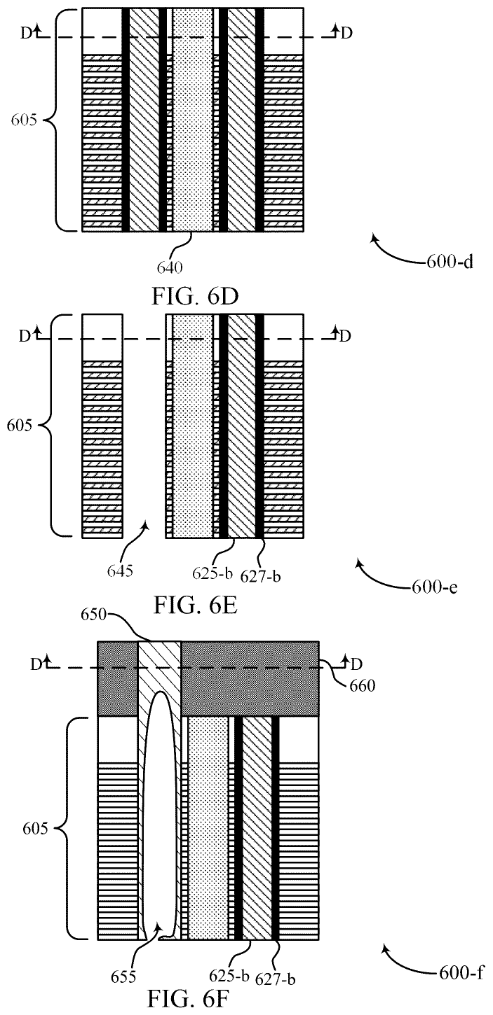

FIG. 6A shows an example of a processing step 600-a that supports memory architectures with partially filled piers in accordance with examples as disclosed herein. The processing step 600-a may include depositing a stack of materials 605. In some instances, the stack of materials 605 may include one or more layers of a nitride material 610 (e.g., a first material) and one or more materials of an oxide material 615 (e.g., a second material).

FIG. 6B shows an example of a processing step 600-b that supports memory architectures with partially filled piers in accordance with examples as disclosed herein. The processing step 600-b may include etching (e.g., removing) one or more portions 620 of the stack of materials 605. For example, a first portion 620-a of the stack of materials 605 may be etched (e.g., removed) and a second portion 620-b of the stack of materials 605 may be etched (e.g., removed). Each of the portions 620 may be etched using either a wet etching operation or a dry etching operation. In some instances, respective piers may be formed in the portions 520 in subsequent processing steps.

FIG. 6C shows an example of a processing step 600-c that supports memory architectures with partially filled piers in accordance with examples as disclosed herein. The processing step 600-c may include depositing one or more materials in the portions 620 to form respective piers 625. In some examples, a singular material such as a dielectric or another type of material may be deposited in the portions 620. In other examples, the materials may include a liner 627 (e.g., a liner material) and a core material. The liner 627 may be a silicon carbon-nitride (SiCN) material, and the core material may be a polysilicon material. In some instances, the liner 627 may be formed on each sidewall of a respective portion 620. That is, the core material may be deposited in each portion 620 such that is in contact with a liner 627 on at least two sides. Additionally, or alternatively, each pier 625 may include a respective cap 630 (e.g., a dielectric cap). In some instances, the respective caps 630 may be located above (e.g., on top of) the stack of materials 605.

Additionally, or alternatively, the processing step 600-c may include performing a metallization process (e.g., a RG process) to form the memory cells. For example, the layers of the nitride material 610 in the stack of materials 605 may be replaced (e.g., metalized) with a metal (e.g., a sixth material) to form access lines (e.g., word lines). The processing step 600-c may also include etching (e.g., removing) one or more portions 635 of the stack of materials 605. For example, a portion 635 of the stack of materials 605 may be etched (e.g., removed) using either a wet etching operation or a dry etching operation. In some instances, electrodes may be formed in the portion 635 and etched back to provide space for the pillars and the memory cells. In some instances, a pillar may be formed in the portion 635 in subsequent processing steps.

FIG. 6D shows an example of a processing step 600-d that supports memory architectures with partially filled piers in accordance with examples as disclosed herein. The processing step 600-d may include depositing a material (e.g., a third material) in the portion 635 to form a pillar 640. In some examples, the material may include a conductive material or another type of material. As used herein, a pillar 640 may refer to the filled portion in the stack of materials 605 that is supplied with voltages to activate the respective memory cells associated with the respective pillar 640. In some cases, a pillars 640 may be formed between each pier 625 and memory cells may be formed between the pillar 640 and the electrodes.

FIG. 6E shows an example of a processing step 600-e that supports memory architectures with partially filled piers in accordance with examples as disclosed herein. The processing step 600-e may include etching (e.g., removing) one or more piers 625 to form respective cavities 645. For example, every-other pier in the stack of materials 605 may be removed to form a respective cavity 645. That is, as shown in FIG. 6E the pier 625-a may be etched (e.g., removed) to form a cavity 645, and the pier 625-b may remain in the stack of materials 605. In some examples, the exhumed piers (e.g., pier 625-a) may be used for subsequent memory cell formation, and the non-exhumed piers (e.g., pier 625-b) may remain intact or may have a portion removed (e.g., the core material may be removed but the liner 627 may remain). The etched piers 625 may be etched using either a wet etching operation or a dry etching operation.

FIG. 6F shows an example of a processing step 600-f that supports memory architectures with partially filled piers in accordance with examples as disclosed herein. The processing step 600-f may include depositing a material 650 (e.g., a fourth material) in the cavity 645. In some instances, the filled cavity 645 may include a respective portion 655 after depositing the material 650. The portion 655 may be completely surrounded by the material 650, or may be partially surrounded by the material 650. For example, before depositing the material 650, another material (e.g., a fifth material) may have been deposited in the cavity 645 (not shown). In some examples, the fifth material may be deposited on the sidewalls of the cavity 645 to narrow a dimension of the opening of the cavity 645.

In some instances, the material 650 may extend above an upper layer (e.g., a top layer) of the stack of materials 605. For example, the material 650 may have initially extended to an upper layer of the stack of materials 605 (e.g., as shown in FIG. 5F). A dielectric material 660 (e.g., a dielectric film, a seventh material) may be deposited above the stack of materials 605, and the stack of materials may have undergone a metallization process (or another type of downstream process) as described herein. After performing the metallization process, the cavity 645 may have been partially exhumed (e.g., opened) to perform a cell integration process (e.g., to form memory cells). After performing the cell integration process, the material 650 may have been deposited (e.g., for a second time). In other examples, depositing the material 650 for a second time may include depositing an eighth material, which may be a same material or a different material as the material 650. Such processing steps may result in the portion 655 being generally larger (e.g., taller) and the material 650 extending above an upper surface of the stack of materials 605.

In some examples, the material 650 may include a dielectric material, a low-k material, or both. In some examples, partially filling the cavity 645 with the material 650 may result in air gaps being formed within the cavity 645. That is, in some instances, the portion 655 may represent an air gap within the cavity 645 or a low-k material in the cavity, each of which may reduce capacitive coupling effects between pillars 640 (e.g., between adjacent pillars 640).

In other examples, the material 650 may be a low-k dielectric material. In such instances, the material 650 may fill (e.g., occupy) at least some or all of the portion 655 (not shown). In other instances, the low-k dielectric material may be air, such that the portion 655 represents an air gap within the cavity 645. In either instance, the presence of the low-k dielectric material may reduce capacitive coupling effects between pillars 640, which may improve the associated system's overall performance.

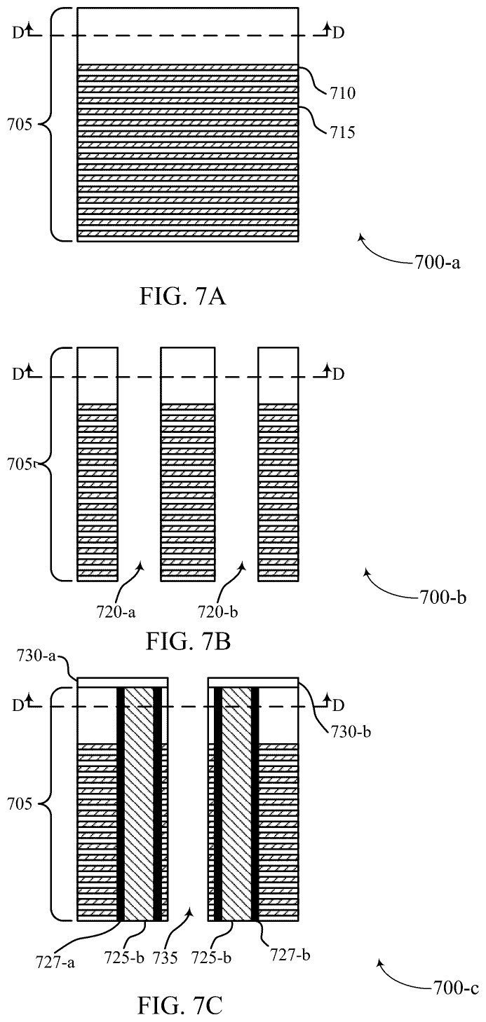

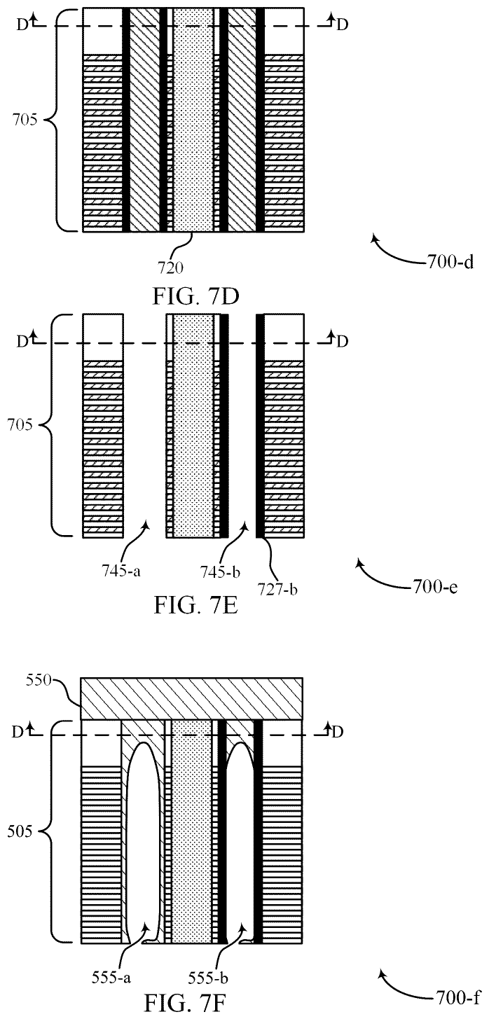

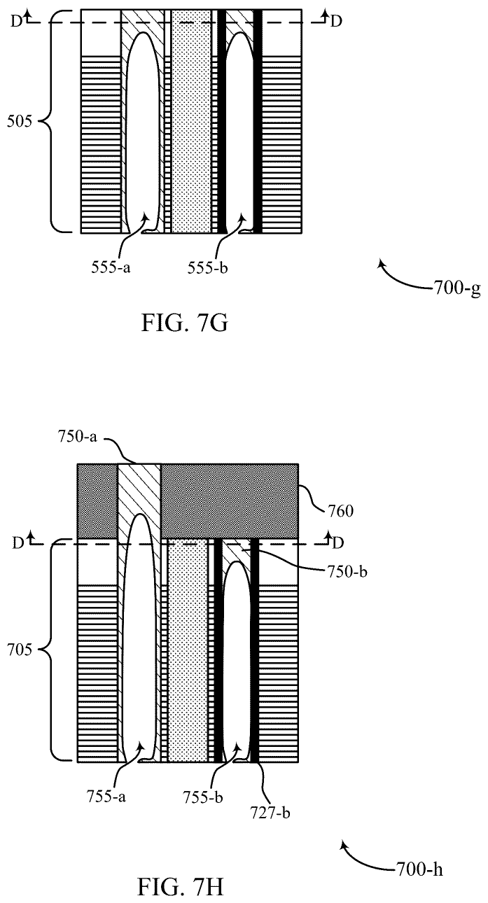

FIG. 7A shows an example of a processing step 700-a that supports memory architectures with partially filled piers in accordance with examples as disclosed herein. The processing step 700-a may include depositing a stack of materials 705. In some instances, the stack of materials 705 may include one or more layers of a nitride material 710 (e.g., a first material) and one or more materials of an oxide material 715 (e.g., a second material).

FIG. 7B shows an example of a processing step 700-b that supports memory architectures with partially filled piers in accordance with examples as disclosed herein. The processing step 700-b may include etching (e.g., removing) one or more portions 720 of the stack of materials 705. For example, a first portion 720-a of the stack of materials 705 may be etched (e.g., removed) and a second portion 720-b of the stack of materials 705 may be etched (e.g., removed). Each of the portions 720 may be etched using either a wet etching operation or a dry etching operation. In some instances, respective piers may be formed in the portions 520 in subsequent processing steps.

FIG. 7C shows an example of a processing step 700-c that supports memory architectures with partially filled piers in accordance with examples as disclosed herein. The processing step 700-c may include depositing one or more materials in the portions 720 to form respective piers 725. In some examples, a singular material such as a dielectric or another type of material may be deposited in the portions 720. In other examples, the materials may include a liner 727 (e.g., a liner material) and a core material. The liner 727 may be a silicon carbon-nitride (SiCN) material, and the core material may be a polysilicon material. In some instances, the liner 727 may be formed on each sidewall of a respective portion 720. That is, the core material may be deposited in each portion 720 such that is in contact with a liner 727 on at least two sides. Additionally, or alternatively, each pier 725 may include a respective cap 730 (e.g., a dielectric cap). In some instances, the respective caps 730 may be located above (e.g., on top of) the stack of materials 705.

Additionally, or alternatively, the processing step 700-c may include performing a metallization process (e.g., a RG process) to form the memory cells. For example, the layers of the nitride material 710 in the stack of materials 705 may be replaced (e.g., metalized) with a metal (e.g., a sixth material) to form access lines (e.g., word lines). The processing step 700-c may also include etching (e.g., removing) one or more portions 735 of the stack of materials 705. For example, a portion 735 of the stack of materials 705 may be etched (e.g., removed) using either a wet etching operation or a dry etching operation. In some instances, electrodes may be formed in the portion 735 and etched back to provide space for the pillars and the memory cells. In some instances, a pillar may be formed in the portion 735 in subsequent processing steps.

FIG. 7D shows an example of a processing step 700-d that supports memory architectures with partially filled piers in accordance with examples as disclosed herein. The processing step 700-d may include depositing a material (e.g., a third material) in the portion 735 to form a pillar 740. In some examples, the material may include a conductive material or another type of material. As used herein, a pillar 740 may refer to the filled portion in the stack of materials 705 that is supplied with voltages to activate the respective memory cells associated with the respective pillar 740. In some cases, a pillars 740 may be formed between each pier 725 and memory cells may be formed between the pillar 740 and the electrodes.

FIG. 7E shows an example of a processing step 700-e that supports memory architectures with partially filled piers in accordance with examples as disclosed herein. The processing step 700-e may include etching (e.g., removing) one or more piers 725 to form respective cavities 745. For example, every pier in the stack of materials 705 may be removed to form a respective cavity 745. That is, as shown in FIG. 7E the pier 725-a may be etched (e.g., removed) to form a cavity 745-a, and the pier 725-b may be etched (e.g., removed) to form a cavity 745-b. In some instances, only the core material may be removed from the pier 725-b. That is, the resulting cavity 745-b may include a liner 727-b on each of its sidewalls. In some examples, the fully-exhumed pier 725-a may be used for subsequent memory cell formation. The etched piers 725 may be etched using either a wet etching operation or a dry etching operation. In some cases, memory cells may be formed between the pillar 740 and the electrodes after removing the piers 725.

FIG. 7F shows an example of a processing step 700-f that supports memory architectures with partially filled piers in accordance with examples as disclosed herein. The processing step 700-f may include depositing a material 750 (e.g., a fourth material) in the cavities 745. In some instances, the filled cavities 745 may include a respective portion 755 after depositing the material 750. The respective portions 755 may be completely surrounded by the material 750, or may be partially surrounded by the material 750. For example, before depositing the material 750, another material (e.g., a fifth material) may have been deposited in the cavity 745 (not shown). In some examples, the fifth material may be deposited on the sidewalls of the cavity 745 to narrow a dimension of the opening of the cavity 745.

In some examples, the material 750 may include a dielectric material, a low-k material, or both. In some examples, partially filling the cavities 745 with the material 750 may result in air gaps being formed within the respective cavities 745. That is, in some instances, the portions 755 may represent air gaps within the cavities 745 or a low-k material in the cavities, each of which may reduce capacitive coupling effects between pillars 740 (e.g., between adjacent pillars 740).

In other examples, the material 750 may be a low-k dielectric material. In such instances, the material 750 may fill (e.g., occupy) at least some or all of the respective portions 755 (not shown). In other instances, the low-k dielectric material may be air, such that the portions 755 represent air gaps within the cavities 745.

FIG. 7G shows an example of a processing step 700-g that supports memory architectures with partially filled piers in accordance with examples as disclosed herein. The processing step 700-g may include planarizing an uppermost surface of the material 750. For example, a process, such as a chemical mechanical planarization (CMP) process, may be performed to remove a portion of the material 750. After removing the portion of the material 750, an uppermost portion of the material 750 may be generally coplanar with an uppermost portion (e.g., a top surface) of the stack of materials 705.

FIG. 7H shows an example of a processing step 700-h that supports memory architectures with partially filled piers in accordance with examples as disclosed herein. The processing step 700-h may include depositing a dielectric material 760 (e.g., a dielectric film, a seventh material) above the stack of materials. That is, in some instances, the material 750-a may extend above an upper layer (e.g., a top layer) of the stack of materials 705 after the CMP process. For example, the material 750-a may have initially extended to an upper layer of the stack of materials 705, similar to the material 750-b. A dielectric material 760 may be deposited above the stack of materials 705, and the stack of materials may have undergone a metallization process (or another type of downstream process) as described herein.

After performing the metallization process, the cavity 745-a may have been partially exhumed (e.g., opened) to perform a cell integration process (e.g., to form memory cells), whereas the cavity 745-b may not have been partially exhumed to perform the cell integration process. After performing the cell integration process using the cavity 745-a, the material 750-a may have been deposited (e.g., for a second time). In other examples, depositing the material 750-a for a second time may include depositing an eighth material, which may be a same material or a different material as the material 750. Such processing steps may result in the portion 755-a being generally larger (e.g., taller) than the portion 755-b, and the material 750-a extending above an upper surface of the stack of materials 705, whereas the material 750-b may generally extend to the upper surface of the stack of materials 705. Accordingly, the processes described herein may reduce capacitive coupling effects between pillars 740, which may improve the associated system's overall performance.

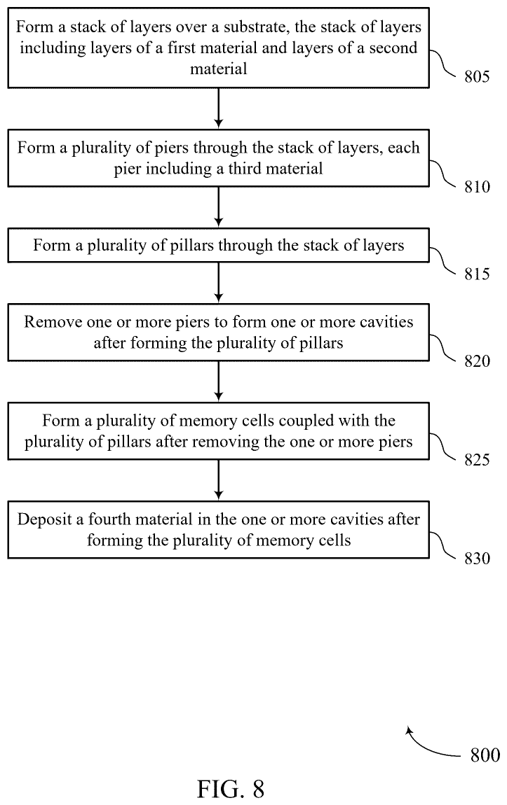

FIG. 8 shows a flowchart illustrating a method 800 that supports memory architectures with partially filled piers in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method may include forming a stack of layers over a substrate, the stack of layers including layers of a first material and layers of a second material.

At 810, the method may include forming a plurality of piers through the stack of layers, each pier including a third material.

At 815, the method may include forming a plurality of pillars through the stack of layers.

At 820, the method may include removing one or more piers to form one or more cavities after forming the plurality of pillars.

At 825, the method may include forming a plurality of memory cells coupled with the plurality of pillars after removing the one or more piers.

At 830, the method may include depositing a fourth material in the one or more cavities after forming the plurality of memory cells.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method, apparatus, or non-transitory computer-readable medium including operations, features, circuitry, logic, means, or instructions, or any combination thereof for forming a stack of layers over a substrate, the stack of layers including layers of a first material and layers of a second material; forming a plurality of piers through the stack of layers, each pier including a third material; forming a plurality of pillars through the stack of layers; removing one or more piers to form one or more cavities after forming the plurality of pillars; forming a plurality of memory cells coupled with the plurality of pillars after removing the one or more piers; and depositing a fourth material in the one or more cavities after forming the plurality of memory cells.
Aspect 2: The method, apparatus, or non-transitory computer-readable medium of aspect 1, where depositing the fourth material in the one or more cavities includes operations, features, circuitry, logic, means, or instructions, or any combination thereof for partially filling the one or more cavities with the fourth material, where the one or more cavities include a respective air gap after depositing the fourth material.
Aspect 3: The method, apparatus, or non-transitory computer-readable medium of any of aspects 1 through 2, where the fourth material includes a low-k dielectric material.
Aspect 4: The method, apparatus, or non-transitory computer-readable medium of any of aspects 1 through 3, further including operations, features, circuitry, logic, means, or instructions, or any combination thereof for depositing a fifth material in the one or more cavities before depositing the fourth material in the one or more cavities, where depositing the fifth material narrows a respective dimension of the one or more cavities in a first direction.
Aspect 5: The method, apparatus, or non-transitory computer-readable medium of any of aspects 1 through 4, further including operations, features, circuitry, logic, means, or instructions, or any combination thereof for performing a metallization process to replace the first material in the stack of layers with a sixth material based at least in part on forming the plurality of piers, where the plurality of memory cells are formed at layers associated with the sixth material after performing the metallization process, where the sixth material includes a conductive material configured to couple with the plurality of memory cells.
Aspect 6: The method, apparatus, or non-transitory computer-readable medium of any of aspects 1 through 5, where removing the one or more piers includes operations, features, circuitry, logic, means, or instructions, or any combination thereof for removing each pier of the plurality of piers.
Aspect 7: The method, apparatus, or non-transitory computer-readable medium of any of aspects 1 through 6, where removing the one or more piers includes operations, features, circuitry, logic, means, or instructions, or any combination thereof for removing every other pier of the plurality of piers.

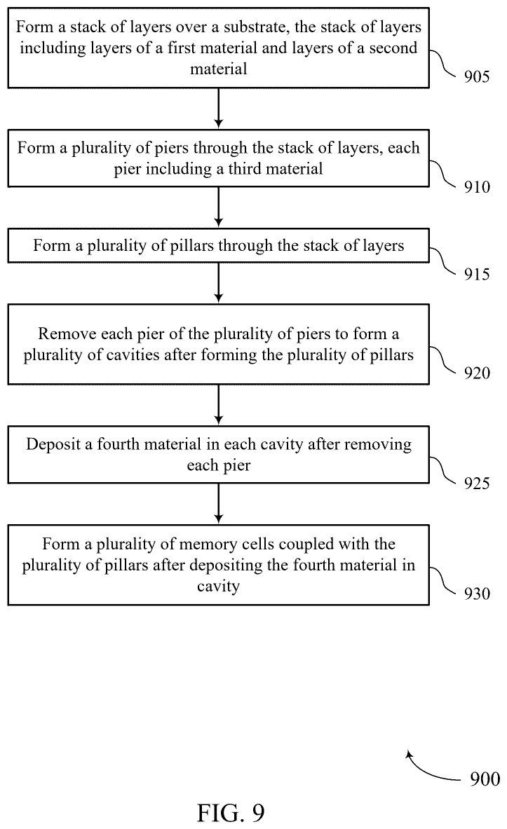

FIG. 9 shows a flowchart illustrating a method 900 that supports memory architectures with partially filled piers in accordance with examples as disclosed herein. The operations of method 900 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 905, the method may include forming a stack of layers over a substrate, the stack of layers including layers of a first material and layers of a second material.

At 910, the method may include forming a plurality of piers through the stack of layers, each pier including a third material.

At 915, the method may include forming a plurality of pillars through the stack of layers.

At 920, the method may include removing each pier of the plurality of piers to form a plurality of cavities after forming the plurality of pillars.

At 925, the method may include depositing a fourth material in each cavity after removing each pier.

At 930, the method may include forming a plurality of memory cells coupled with the plurality of pillars after depositing the fourth material in cavity.

In some examples, an apparatus (e.g., a manufacturing system) as described herein may perform a method or methods, such as the method 900. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 8: A method, apparatus, or non-transitory computer-readable medium including operations, features, circuitry, logic, means, or instructions, or any combination thereof for forming a stack of layers over a substrate, the stack of layers including layers of a first material and layers of a second material; forming a plurality of piers through the stack of layers, each pier including a third material; forming a plurality of pillars through the stack of layers; removing each pier of the plurality of piers to form a plurality of cavities after forming the plurality of pillars; depositing a fourth material in each cavity after removing each pier; and forming a plurality of memory cells coupled with the plurality of pillars after depositing the fourth material in cavity.
Aspect 9: The method, apparatus, or non-transitory computer-readable medium of aspect 8, further including operations, features, circuitry, logic, means, or instructions, or any combination thereof for depositing a first liner in a first cavity of the plurality of cavities before depositing the fourth material in each cavity.
Aspect 10: The method, apparatus, or non-transitory computer-readable medium of aspect 9, further including operations, features, circuitry, logic, means, or instructions, or any combination thereof for depositing a second liner in a second cavity of the plurality of cavities, where the second liner is different than the first liner.
Aspect 11: The method, apparatus, or non-transitory computer-readable medium of any of aspects 8 through 10, where depositing the fourth material in each cavity includes operations, features, circuitry, logic, means, or instructions, or any combination thereof for partially filling each cavity with the fourth material, where each cavity includes a respective air gap after depositing the fourth material.
Aspect 12: The method, apparatus, or non-transitory computer-readable medium of any of aspects 8 through 11, where the fourth material includes a low-k dielectric material.
Aspect 13: The method, apparatus, or non-transitory computer-readable medium of any of aspects 8 through 12, further including operations, features, circuitry, logic, means, or instructions, or any combination thereof for depositing a fifth material in each cavity before depositing the fourth material in each cavity, where depositing the fifth material narrows a respective dimension of each cavity in a first direction.
Aspect 14: The method, apparatus, or non-transitory computer-readable medium of any of aspects 8 through 13, further including operations, features, circuitry, logic, means, or instructions, or any combination thereof for performing a metallization process to replace the first material in the stack of layers with a sixth material based at least in part on forming the plurality of piers, where the plurality of memory cells are formed at layers associated with the sixth material after performing the metallization process, where the sixth material includes a conductive material configured to couple with the plurality of memory cells.
Aspect 15: The method, apparatus, or non-transitory computer-readable medium of any of aspects 8 through 14, further including operations, features, circuitry, logic, means, or instructions, or any combination thereof for depositing a seventh material above the plurality of cavities and the plurality of pillars after depositing the fourth material in each cavity.
Aspect 16: The method, apparatus, or non-transitory computer-readable medium of aspect 15, further including operations, features, circuitry, logic, means, or instructions, or any combination thereof for removing the seventh material located above a first cavity of the plurality of cavities, where forming a subset of the plurality of memory cells coupled with a first pillar of the plurality of pillars is based at least in part on removing the seventh material located above the first cavity and depositing an eighth material after removing the seventh material located above the first cavity.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 17: An apparatus, including: a substrate; a stack of layers including layers of a first material and layers of a second material; a plurality of first piers extending through the stack of layers, where a sub-portion of each pier of the plurality of first piers includes a third material; a plurality of second piers extending through the stack of layers; a plurality of pillars extending through the stack of layers, where each pillar is positioned between a first pier of the plurality of first piers and a second pier of the plurality of second piers; and a plurality of memory cells coupled with the plurality of pillars, where each memory cell is positioned at layers associated with the first material.
Aspect 18: The apparatus of aspect 17, where each pier of the plurality of first piers includes a respective air gap.
Aspect 19: The apparatus of any of aspects 17 through 18, where a portion of each pier of the plurality of second piers includes the third material, and each pier of the plurality of second piers includes a respective air gap.
Aspect 20: The apparatus of any of aspects 17 through 19, where the third material includes a low-k material.
Aspect 21: The apparatus of any of aspects 17 through 20, where the first pier of the plurality of first piers includes a greater dimension in a second direction than a first pier of the plurality of second piers.
Aspect 22: The apparatus of any of aspects 17 through 21, where a portion of each pier of the plurality of second piers includes the third material, and the second pier of the plurality of second piers includes a first liner.
Aspect 23: The apparatus of aspect 22, where a second pier of the plurality of first piers includes a second liner different than the first liner.
Aspect 24: The apparatus of any of aspects 17 through 23, where memory cells of the plurality of memory cells are symmetrically located between respective piers of the plurality of first piers.
Aspect 25: The apparatus of any of aspects 17 through 24, where the plurality of second piers alternate with the plurality of first piers along a first direction.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a stack of layers over a substrate, the stack of layers comprising layers of a first material and layers of a second material;
forming a plurality of piers through the stack of layers, each pier comprising a third material;
forming a plurality of pillars through the stack of layers;
removing one or more piers to form one or more cavities after forming the plurality of pillars;
forming a plurality of memory cells coupled with the plurality of pillars after removing the one or more piers; and
depositing a fourth material in the one or more cavities after forming the plurality of memory cells.

2. The method of claim 1, wherein depositing the fourth material in the one or more cavities comprises:
partially filling the one or more cavities with the fourth material, wherein the one or more cavities comprise a respective air gap after depositing the fourth material.

3. The method of claim 1, wherein the fourth material comprises a low-k dielectric material.

4. The method of claim 1, further comprising:
depositing a fifth material in the one or more cavities before depositing the fourth material in the one or more cavities, wherein depositing the fifth material narrows a respective dimension of the one or more cavities in a first direction.

5. The method of claim 1, further comprising:
performing a metallization process to replace the first material in the stack of layers with a sixth material based at least in part on forming the plurality of piers, wherein the plurality of memory cells are formed at layers associated with the sixth material after performing the metallization process, wherein the sixth material comprises a conductive material configured to couple with the plurality of memory cells.

6. The method of claim 1, wherein removing the one or more piers comprises:
removing each pier of the plurality of piers.

7. The method of claim 1, wherein removing the one or more piers comprises:
removing every other pier of the plurality of piers.

8. A method, comprising:
forming a stack of layers over a substrate, the stack of layers comprising layers of a first material and layers of a second material;
forming a plurality of piers through the stack of layers, each pier comprising a third material;
forming a plurality of pillars through the stack of layers;
removing each pier of the plurality of piers to form a plurality of cavities after forming the plurality of pillars;
depositing a fourth material in each cavity after removing each pier; and
forming a plurality of memory cells coupled with the plurality of pillars after depositing the fourth material in cavity.

9. The method of claim 8, further comprising:
depositing a first liner in a first cavity of the plurality of cavities before depositing the fourth material in each cavity.

10. The method of claim 9, further comprising:
depositing a second liner in a second cavity of the plurality of cavities, wherein the second liner is different than the first liner.

11. The method of claim 8, wherein depositing the fourth material in each cavity comprises:
partially filling each cavity with the fourth material, wherein each cavity comprises a respective air gap after depositing the fourth material.

12. The method of claim 8, wherein the fourth material comprises a low-k dielectric material.

13. The method of claim 8, further comprising:
depositing a fifth material in each cavity before depositing the fourth material in each cavity, wherein depositing the fifth material narrows a respective dimension of each cavity in a first direction.

14. The method of claim 8, further comprising:
performing a metallization process to replace the first material in the stack of layers with a sixth material based at least in part on forming the plurality of piers, wherein the plurality of memory cells are formed at layers associated with the sixth material after performing the metallization process, wherein the sixth material comprises a conductive material configured to couple with the plurality of memory cells.

15. The method of claim 8, further comprising:
depositing a seventh material above the plurality of cavities and the plurality of pillars after depositing the fourth material in each cavity.

16. The method of claim 15, further comprising:
removing the seventh material located above a first cavity of the plurality of cavities, wherein forming a subset of the plurality of memory cells coupled with a first pillar of the plurality of pillars is based at least in part on removing the seventh material located above the first cavity; and
depositing an eighth material after removing the seventh material located above the first cavity.

17. An apparatus, comprising:
a substrate;
a stack of layers comprising layers of a first material and layers of a second material;
a plurality of first piers extending through the stack of layers, wherein a sub-portion of each pier of the plurality of first piers comprises a third material;
a plurality of second piers extending through the stack of layers;
a plurality of pillars extending through the stack of layers, wherein each pillar is positioned between a first pier of the plurality of first piers and a second pier of the plurality of second piers; and
a plurality of memory cells coupled with the plurality of pillars, wherein each memory cell is positioned at layers associated with the first material.

18. The apparatus of claim 17, wherein each pier of the plurality of first piers comprises a respective air gap.

19. The apparatus of claim 17, wherein:
a portion of each pier of the plurality of second piers comprises the third material, and
each pier of the plurality of second piers comprises a respective air gap.

20. The apparatus of claim 17, wherein the third material comprises a low-k material.

21. The apparatus of claim 17, wherein the first pier of the plurality of first piers comprises a greater dimension in a second direction than a first pier of the plurality of second piers.

22. The apparatus of claim 17, wherein:
a portion of each pier of the plurality of second piers comprises the third material, and
the second pier of the plurality of second piers comprises a first liner.

23. The apparatus of claim 22, wherein a second pier of the plurality of first piers comprises a second liner different than the first liner.

24. The apparatus of claim 17, wherein memory cells of the plurality of memory cells are symmetrically located between respective piers of the plurality of first piers.

25. The apparatus of claim 17, wherein the plurality of second piers alternate with the plurality of first piers along a first direction.
